(19) United States
(12) Patent Application Publication
(10) Pub. No.: US 2022/0290302 A1
(43) Pub. Date: Sep. 15, 2022

(54) SUBSTRATE LIQUID PROCESSING METHOD, SUBSTRATE LIQUID PROCESSING APPARATUS, AND COMPUTER-READABLE RECORDING MEDIUM

(71) Applicant: Tokyo Electron Limited, Tokyo (JP)

(72) Inventors: Kazutoshi Iwai, Kikuchi-gun, Kumamoto (JP); Yuichiro Inatomi, Kikuchi-gun, Kumamoto (JP); Takafumi Niwa, Kikuchi-gun, Kumamoto (JP)

(21) Appl. No.: 17/753,264

(22) PCT Filed: Aug. 14, 2020
(86) PCT No.: PCT/JP2020/030836

§ 371 Date: Feb. 25, 2022

(30) Foreign Application Priority Data
Aug. 27, 2019 (JP) 2019-154802

(51) Int. Cl. C23C 18/16

(52) U.S. Cl. CPC C23C 18/168

(57) ABSTRACT

A substrate liquid processing method includes preparing a substrate having a surface including a recess on which a seed layer is stacked; supplying an electroless plating liquid onto the surface of the substrate to fill the recess with the electroless plating liquid while forming a liquid film of the electroless plating liquid on the surface; and adjusting a temperature of the liquid film from a first temperature at which a metal is precipitated on the seed layer to a second temperature lower than the first temperature to fill the recess with the metal starting from a bottom portion of the recess such that a void is not formed therein.

### TECHNICAL FIELD

The various aspects and embodiments described herein pertain generally to a substrate liquid processing method, a substrate liquid processing apparatus, and a computer-readable recording medium.

### BACKGROUND

In an electroless plating, precipitation of a plating metal on a substrate can be accelerated by heating a plating liquid on the substrate. For example, Patent Document 1 discloses a substrate liquid processing apparatus capable of rapidly increasing a temperature of the plating liquid on a substrate by covering the substrate with a cover having a heater.

### PRIOR ART DOCUMENT

Patent Document 1: Japanese Patent Laid-open Publication No. 2018-003097

### DISCLOSURE OF THE INVENTION

### Problems to be Solved by the Invention

Exemplary embodiments provide a technique advantageous for burying a metal in a recess on a surface of a substrate in an electroless plating processing without forming a void.

### Means for Solving the Problems

In an exemplary embodiment, a substrate liquid processing method includes preparing a substrate having a surface including a recess on which a seed layer is stacked; supplying an electroless plating liquid onto the surface of the substrate to fill the recess with the electroless plating liquid while forming a liquid film of the electroless plating liquid on the surface; and adjusting a temperature of the liquid film from a first temperature at which a metal is precipitated on the seed layer to a second temperature lower than the first temperature to fill the recess with the metal starting from a bottom portion of the recess such that a void is not formed therein.

### Effect of the Invention

According to the exemplary embodiment, it is possible to provide a technique advantageous for burying the metal in the recess on the surface of the substrate in the electroless plating processing without forming the void.

### BRIEF DESCRIPTION OF THE DRAWINGS

FIG. 1 is a schematic diagram illustrating a configuration of a plating apparatus as an example of a substrate liquid processing apparatus.

FIG. 2 is a schematic cross sectional view illustrating an example of a plating device.

FIG. 3 is a flowchart illustrating an example of an electroless plating processing according to a first exemplary embodiment.

FIG. 4 presents a graph showing an example of a relationship between a processing time and a temperature of a plating liquid in the electroless plating processing according to the first exemplary embodiment.

FIG. 5A is a diagram illustrating a cross sectional state of a recess of a substrate in the electroless plating processing according to the first exemplary embodiment.

FIG. 5B is a diagram illustrating a cross sectional state of the recess of the substrate in the electroless plating processing according to the first exemplary embodiment.

FIG. 5C is a diagram illustrating a cross sectional state of the recess of the substrate in the electroless plating processing according to the first exemplary embodiment.

FIG. 6 is a flowchart illustrating an example of an electroless plating processing according to a second exemplary embodiment.

FIG. 7 is a graph showing an example of a relationship between a processing time and a temperature of a plating liquid in the electroless plating processing according to the second exemplary embodiment.

FIG. 8 is a flowchart illustrating an example of an electroless plating processing according to a third exemplary embodiment.

FIG. 9 is a graph showing an example of a relationship between a processing time and a temperature of a plating liquid in the electroless plating processing according to the third exemplary embodiment.

FIG. 10A is a diagram illustrating a cross sectional state of a recess of a substrate in the electroless plating processing according to the third exemplary embodiment.

FIG. 10B is a diagram illustrating a cross sectional state of the recess of the substrate in the electroless plating processing according to the third exemplary embodiment.

FIG. 10C is a diagram illustrating a cross sectional state of the recess of the substrate in the electroless plating processing according to the third exemplary embodiment.

FIG. 10D is a diagram illustrating a cross sectional state of the recess of the substrate in the electroless plating processing according to the third exemplary embodiment.

FIG. 10E is a diagram illustrating a cross sectional state of the recess of the substrate in the electroless plating processing according to the third exemplary embodiment.

FIG. 11 is a flowchart illustrating an example of an electroless plating processing according to a fourth exemplary embodiment.

FIG. 12 is a graph showing an example of a relationship between a processing time and a temperature of a plating liquid in the electroless plating processing according to the fourth exemplary embodiment.

### DETAILED DESCRIPTION

Hereinafter, an example of a substrate liquid processing apparatus and a substrate liquid processing method will be described with reference to the accompanying drawings.

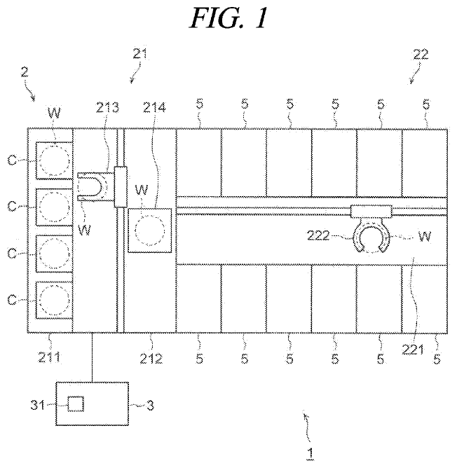

First, a configuration of a substrate liquid processing apparatus will be described with reference to FIG. 1. FIG. 1 is a schematic diagram illustrating a configuration of a plating apparatus as an example of the substrate liquid processing apparatus. Here, the plating apparatus is an apparatus configured to perform a plating processing on a substrate W by supplying a plating liquid onto the substrate W.

As shown in FIG. 1, a plating apparatus 1 includes a plating unit 2 and a controller 3 configured to control an operation of the plating unit 2.

The plating unit 2 is configured to perform various processings on the substrate (wafer) W. The processings performed by the plating unit 2 will be described later.

The controller 3 is, for example, a computer, and includes an operation controller and a storage. The operation controller is configured as, for example, a CPU (Central Processing Unit) and configured to control the operation of the plating unit 2 by reading and executing a program stored in the storage. The storage is configured as a storage device such as a RAM (Random Access Memory), a ROM (Read Only Memory) or a hard disk, and stores therein the program for controlling various processings performed in the plating unit 2. Further, the program may be recorded in a computer-readable recording medium 31, or may be installed from the recording medium 31 to the storage. The computer-readable recording medium 31 may be, for example, a hard disc (HD), a flexible disc (FD), a compact disc (CD), a magneto optical disc (MO), or a memory card. The recording medium 31 stores therein a program that, when executed by a computer for controlling an operation of the plating apparatus 1, causes the computer to control the plating apparatus 1 to perform a plating method to be described later.

Referring to FIG. 1, a configuration of the plating unit 2 will be elaborated. FIG. 1 is a schematic plan view illustrating the configuration of the plating unit 2.

The plating unit 2 is equipped with a carry-in/out station 21; and a processing station 22 provided adjacent to the carry-in/out station 21.

The carry-in/out station 21 includes a placing section 211 and a transfer section 212 provided adjacent to the placing section 211.

In the placing section 211, a plurality of transfer containers (hereinafter, referred to as “carriers C”) each of which accommodates therein a plurality of substrates W horizontally is placed.

The transfer section 212 includes a transfer mechanism 213 and a delivery unit 214. The transfer mechanism 213 includes a holding mechanism configured to hold a substrate W, and is configured to be movable horizontally and vertically and pivotable around a vertical axis.

The processing station 22 includes plating devices 5. In the present exemplary embodiment, the number of plating devices 5 provided in the processing station 22 is two or more, but may be one. The plating devices 5 are arranged on both sides of a transfer path 221 which is extended in a predetermined direction (on both sides in a direction perpendicular to a moving direction of a transfer mechanism 222 to be described later).

The transfer path 221 is provided with the transfer mechanism 222. The transfer mechanism 222 includes a holding mechanism configured to hold a substrate W, and is configured to be movable horizontally and vertically and pivotable around a vertical axis.

In the plating unit 2, the transfer mechanism 213 of the carry-in/out station 21 is configured to transfer the substrate W between the carrier C and the delivery unit 214. Specifically, the transfer mechanism 213 takes out the substrate W from the carrier C placed in the placing section 211, and then, places the substrate W in the delivery unit 214. Further, the transfer mechanism 213 takes out the substrate W which is placed in the delivery unit 214 by the transfer mechanism 222 of the processing station 22, and then, accommodates the substrate W in the carrier C of the placing section 211.

In the plating unit 2, the transfer mechanism 222 of the processing station 22 is configured to transfer the substrate W between the delivery unit 214 and the plating device 5 and between the plating device 5 and the delivery unit 214. Specifically, the transfer mechanism 222 takes out the substrate W placed in the delivery unit 214 and carries the substrate W into the plating device 5. Further, the transfer mechanism 222 takes out the substrate W from the plating device 5 and places the substrate W in the delivery unit 214.

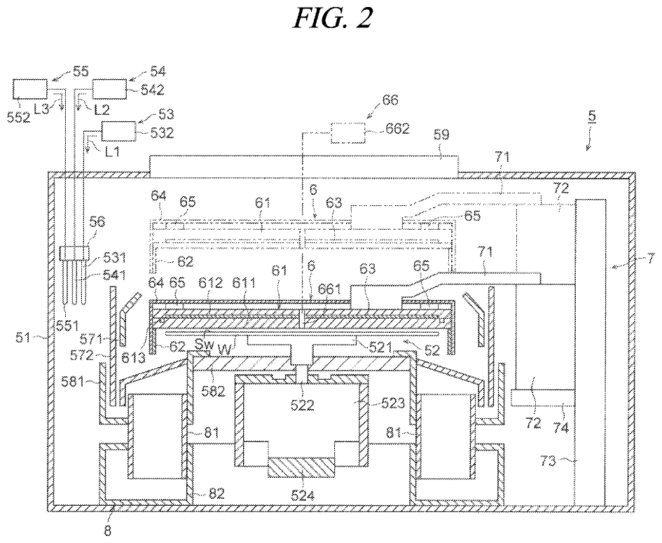

Hereinafter, a configuration of the plating device 5 will be described. FIG. 2 is a schematic cross-sectional view showing a configuration of the plating device 5.

The plating device 5 is configured to perform a liquid processing including an electroless plating processing. This plating device 5 is equipped with a chamber 51; a substrate holder 52 disposed within the chamber 51 and configured to hold the substrate W horizontally; and a plating liquid supply 53 configured to supply a plating liquid L1 onto a top surface (processing surface Sw) of the substrate W held by the substrate holder 52. In the present exemplary embodiment, the substrate holder 52 includes a chuck member 521 configured to vacuum-attract a bottom surface (rear surface) of the substrate W. This substrate holder 52 is of a so-called vacuum chuck type.

The substrate holder 52 is connected to a rotation motor 523 (rotational driving unit) via a rotation shaft 522. When the rotation motor 523 is driven, the substrate holder 52 is rotated along with the substrate W thereon. The rotation motor 523 is supported at a base 524 fixed to the chamber 51.

The plating liquid supply 53 is equipped with a plating liquid nozzle 531 configured to discharge (supply) the plating liquid L1 onto the substrate W held by the substrate holder 52, and a plating liquid source 532 configured to supply the plating liquid L1 to the plating liquid nozzle 531. The plating liquid source 532 is configured to supply the plating liquid L1 heated to or adjusted to have a predetermined temperature to the plating liquid nozzle 531. A temperature of the plating liquid L1 when the plating liquid L1 is discharged from the plating liquid nozzle 531 is, for example, equal to or larger than 55° C. and equal to or smaller than 75° C., and more desirably, equal to or larger than 60° C. and equal to or smaller than 70° C. The plating liquid nozzle 531 is held by a nozzle arm 56 and configured to be movable.

The plating liquid L1 is an autocatalytic (reduction) plating liquid for electroless plating. The plating liquid L1 contains a metal ion such as a cobalt (Co) ion, a nickel (Ni) ion, a tungsten (W) ion, a copper (Cu) ion, a palladium (Pd) ion or a gold (Au) ion, and a reducing agent such as hypophosphorous acid or dimethylamine borane. The plating liquid L1 may further contain an additive or the like. A plating film (metal film) formed by the plating processing with the plating liquid L1 may be, for example, Cu, CoWB, CoB, CoWP, CoWBP, NiWB, NiB, NiWP, NiWBP, or the like.

The plating device 5 according to the present exemplary embodiment further includes, as other processing liquid supplies, a cleaning liquid supply 54 configured to supply a cleaning liquid L2 onto the upper surface of the substrate W held by the substrate holder 52, and a rinse liquid supply 55 configured to supply a rinse liquid L3 onto the upper surface of the substrate W.

The cleaning liquid supply 54 is equipped with a cleaning liquid nozzle 541 configured to discharge the cleaning liquid L2 onto the substrate W held by the substrate holder 52, and a cleaning liquid source 542 configured to supply the cleaning liquid L2 to the cleaning liquid nozzle 541. Examples of the cleaning liquid L2 may include an organic acid such as a formic acid, a malic acid, a succinic acid, a citric acid or a malonic acid, or a hydrofluoric acid (DHF) (aqueous solution of hydrogen fluoride) diluted to the extent that it does not corrode a plating target surface of the substrate W. The cleaning liquid nozzle 541 is held by the nozzle arm 56 and configured to be movable along with the plating liquid nozzle 531.

The rinse liquid supply 55 is equipped with a rinse liquid nozzle 551 configured to supply the rinse liquid L3 onto the substrate W held by the substrate holder 52, and a rinse liquid source 552 configured to supply the rinse liquid L3 to the rinse liquid nozzle 551. The rinse liquid nozzle 551 is held by the nozzle arm 56 and configured to be movable along with the plating liquid nozzle 531 and the cleaning liquid nozzle 541. Examples of the rinse liquid L3 may include pure water or the like.

The nozzle arm 56 holding the above-described plating liquid nozzle 531, cleaning liquid nozzle 541 and rinse liquid nozzle 551 is connected to a non-illustrated nozzle moving mechanism. The nozzle moving mechanism is configured to move the nozzle arm 56 horizontally and vertically. More specifically, the nozzle arm 56 is configured to be movable by the nozzle moving mechanism between a discharge position where the processing liquid (plating liquid L1, cleaning liquid L2 or rinse liquid L3) is discharged onto the substrate W and a retreat position retreated from the discharge position. The discharge position is not particularly limited as long as the processing liquid can be supplied onto a certain position on the upper surface of the substrate W. For example, desirably, the discharge position is set to a position where the processing liquid can be supplied to a center of the substrate W. The discharge position of the nozzle arm 56 may be set differently in the individual cases of supplying the plating liquid L1, supplying the cleaning liquid L2 and supplying the rinse liquid L3 to the substrate W. The retreat position is a position within the chamber 51 which does not overlap with the substrate W when viewed from above and is spaced apart from the discharge position. When the nozzle arm 56 is located at the retreat position, it is possible to avoid interference between a cover body 6 being moved and the nozzle arm 56.

A cup 571 is disposed around the substrate holder 52. The cup 571 is formed into a ring shape when viewed from above and configured to receive the processing liquid scattered from the substrate W when the substrate W is being rotated and configured to guide the received processing liquid to a drain duct 581 to be described later. An atmosphere blocking cover 572 is provided at an outer peripheral side of the cup 571 and configured to suppress diffusion of the ambient atmosphere around the substrate W in the chamber 51. The atmosphere blocking cover 572 is formed into a vertically extending cylindrical shape and has an open top. The cover body 6 to be descried later can be inserted into the atmosphere blocking cover 572 from above.

The drain duct 581 is provided under the cup 571. The drain duct 581 is formed into a ring shape when viewed from above, and serves to drain the processing liquid falling down after being received by the cup 571 and the processing liquid directly falling down from the vicinity of the substrate W. An inner cover 582 is provided at an inner periphery side of the drain duct 581.

The substrate W held by the substrate holder 52 is covered by the cover body 6. The cover body 6 has a ceiling member 61 and a sidewall 62 extending downwards from the ceiling member 61. The ceiling member 61 is disposed above the substrate W held by the substrate holder 52 when the cover body 6 is located at a lower position to be described later, facing the substrate W at a relatively small gap therebetween.

The ceiling member 61 includes a first ceiling plate 611 and a second ceiling plate 612 provided on the first ceiling plate 611. A heater 63 (heating unit) is interposed between the first ceiling plate 611 and the second ceiling plate 612. The first ceiling plate 611 and the second ceiling plate 612 are provided as a first planar body and a second planar body with the heater 63 interposed therebetween. The first ceiling plate 611 and the second ceiling plate 612 are configured to seal the heater 63 such that the heater 63 is not brought into contact with the processing liquid such as the plating liquid L1. More specifically, a seal ring 613 is provided at an outer peripheral side of the heater 63 between the first ceiling plate 611 and the second ceiling plate 612, and the heater 63 is sealed by the seal ring 613. Desirably, the first ceiling plate 611 and the second ceiling plate 612 have corrosion resistance against the processing liquid such as the plating liquid L1, and may be made of, for example, an aluminum alloy. Further, to improve the corrosion resistance, the first ceiling plate 611, the second ceiling plate 612 and the sidewall member 62 may be coated with Teflon (registered trademark).

The cover body 6 is connected to a cover body moving mechanism 7 via a cover body arm 71. The cover body moving mechanism 7 is configured to move the cover body 6 horizontally and vertically. More specifically, the cover body moving mechanism 7 is equipped with a rotation motor 72 configured to move the cover body 6 horizontally and a cylinder 73 (gap adjusting unit) configured to move the cover body 6 vertically. The rotation motor 72 is provided on a supporting plate 74 configured to be movable up and down with respect to the cylinder 73. Here, instead of the cylinder 73, an actuator (not shown) including a motor and a ball screw may be used.

The rotation motor 72 of the cover body moving mechanism 7 is configured to move the cover body 6 between an upper position located above the substrate W held by the substrate holder 52 and a retreat position retreated from the upper position. The upper position is a position facing the substrate W, which is held by the substrate holder 52, with a relatively large gap therebetween and overlapping with the substrate W when viewed from above. The retreat position is a position within the chamber 51 which does not overlap with the substrate W when viewed from above. When the cover body 6 is located at the retreat position, it is possible to avoid the interference between the nozzle arm 56 being moved and the cover body 6. A rotation axis of the rotation motor 72 is vertically extended, and the cover body 6 is configured to be pivotable horizontally between the upper position and the retreat position.

The cylinder 73 of the cover body moving mechanism 7 is configured to move the cover body 6 up and down and adjust the distance between the first ceiling plate 611 of the ceiling member 61 and the upper surface Sw of the substrate W on which the plating liquid L1 is accumulated. More specifically, the cylinder 73 locates the cover body 6 at the lower position (indicated by a solid line in FIG. 2) and the upper position (indicated by a dashed double-dotted line in FIG. 2).

When the cover body 6 is placed at the lower position, the first ceiling plate 611 comes close to the substrate W. In this case, in order to suppress contamination and loss of the plating liquid L1 or to suppress generation of bubbles in the plating liquid L1, the lower position is set such that the first ceiling plate 611 is not brought into contact with the plating liquid L1 on the substrate W.

The upper position is set to a position where it is possible to avoid interference of the cover body 6 with the ambient structures such as the cup 571 and the atmosphere blocking cover 572 when the cover body 6 is pivoted horizontally.

In the present exemplary embodiment, when the heater 63 is driven and the cover body 6 is located at the aforementioned lower position, the plating liquid L1 on the substrate W is heated.

The sidewall member 62 of the cover body 6 is extended downwards from a periphery of the first ceiling plate 611 of the ceiling member 61 and located at an outer peripheral side of the substrate W when the plating liquid L1 on the substrate W is heated (i.e., when the cover body 6 is located at the lower position). When the cover body 6 is placed at the lower position, a lower end of the sidewall member 62 may be located at a position lower than the substrate W.

The heater 63 is provided in the ceiling member 61 of the cover body 6. The heater 63 heats the processing liquid (appropriately, the plating liquid L1) on the substrate W when the cover body 6 is located at the lower position. In the present exemplary embodiment, the heater 63 is disposed between the first ceiling plate 611 and the second ceiling plate 612 of the cover body 6 and is sealed as described above. Thus, the processing liquid such as the plating liquid L is suppressed from coming into contact with the heater 63.

In the present exemplary embodiment, an inert gas (for example, a nitrogen (N₂) gas) is supplied to the inside of the cover body 6 by an inert gas supply 66. This inert gas supply 66 is equipped with a gas nozzle 661 configured to discharge the inert gas to the inside of the cover body 6; and an inert gas source 662 configured to supply the inert gas to the gas nozzle 661. The gas nozzle 661 is provided at the ceiling member 61 of the cover body 6 and is configured to discharge the inert gas toward the substrate W in the state that the substrate W is covered with the cover body 6.

The ceiling member 61 and the sidewall member 62 of the cover body 6 are covered by a cover body cover 64. The cover body cover 64 is provided on the second ceiling plate 612 of the cover body 6 with supporting members 65 therebetween. That is, a plurality of supporting members 65 protruded upwards from an upper surface of the second ceiling plate 612 is provided on the second ceiling plate 612, and the cover body cover 64 is placed on these supporting members 65. The cover body cover 64 is configured to be movable horizontally and vertically along with the cover body 6. Further, it is desirable that the cover body cover 64 has higher thermal insulation property than the ceiling member 61 and the sidewall member 62 to suppress a leakage of the heat within the cover body 6 to the vicinity thereof. For example, desirably, the cover body cover 64 may be made of a resin material. More desirably, the resin material has thermal resistance.

A fan filter unit 59 (gas supply) configured to supply clean air (gas) around the cover body 6 is provided at a top portion of the chamber 51. The fan filter unit 59 supplies air into the chamber 51 (particularly, into the atmosphere blocking cover 572), and the supplied air flows toward an exhaust line 81 to be described later. A downflow of this air is formed around the cover body 6, and a gas vaporized from the processing liquid such as the plating liquid L1 flows toward the exhaust line 81 along with this downflow. Accordingly, it is possible to suppress the rise and diffusion of the gas vaporized from the processing liquid within the chamber 51.

The gas supplied from the fan filter unit 59 is exhausted by a gas exhaust mechanism 8. The gas exhaust mechanism 8 is equipped with two exhaust lines 81 provided under the cup 571 and an exhaust duct 82 provided under the drain duct 581. The two exhaust lines 81 penetrate a bottom portion of the drain duct 581 and individually communicate with the exhaust duct 82. The exhaust duct 82 is formed into a substantially semi-circular ring shape when viewed from above. In the present exemplary embodiment, the single exhaust duct 82 is provided under the drain duct 581 and the two exhaust lines 81 communicate with this exhaust duct 82.

(Electroless Plating Processing)

Now, a flow of the electroless plating processing performed by the above-described plating device 5 will be explained.

Hereinafter, as an example, a case where the plating liquid L1 contains copper ions and copper is filled, as a plating metal, in a recess (for example, a via (hole) or a trench (groove)) on the processing surface Sw of the substrate W by the electroless plating processing will be explained. However, the technique to be described below is still advantageous even when a metal other than the copper is used as a plating metal.

In the technique of forming a wiring by burying copper in the recess of the processing surface Sw of the substrate W, a seed layer containing copper or cobalt is stacked on a surface of the recess, and the copper can be buried in the recess by performing an electroless plating using the seed layer as a catalytic surface. In this case, copper film formation in the recess does not necessarily proceed uniformly depending on the state of the seed layer or the like. For example, the copper film formation may proceed faster in an opening portion of the recess than in a bottom portion or a central portion thereof. In this case, before the filling of the copper in the bottom portion or the central portion of the recess is completed, the filling of the copper in the opening portion of the recess may be completed, causing a cavity (that is, a void) in which the copper is not buried to be formed inside the recess.

In order to suppress the formation of such a void, it is effective to perform the electroless plating processing while controlling a film forming rate of the copper in the recess. That is, by suppressing the film forming rate of the copper in the opening portion of the recess as compared to the film forming rate of the copper in the bottom or central portion of the recess, the opening portion can be suppressed from being closed by the copper before the filling of the copper in the bottom portion or the central portion of the recess is completed. For example, by using the plating liquid L1 mixed with a complexing agent or an inhibitor configured to inhibit a plating reaction, the film forming rate of the copper in the opening portion of the recess can be suppressed.

However, depending on the size of the recess (for example, an opening diameter) or the thickness of the seed layer, the complexing agent or the inhibitor may not necessarily suppress the film forming rate of the copper in the opening portion of the recess sufficiently. By way of example, when the seed layer is formed by PVD (Physical Vapor Deposition), a deposition amount of the seed layer near the opening portion of the recess tends to be relatively large, so the diameter of the opening portion may be easily reduced due to the seed layer. When the diameter of the opening portion of the recess is small, even if the film forming rate of the copper in the opening portion is suppressed by the inhibitor contained in the plating liquid, the opening may be closed by the copper before the copper is completely filled in the bottom portion or the central portion of the recess.

As a result of intensive research, the inventors of the present application have found a film formation technique featuring a multi-step temperature control based on a phenomenon that a relationship between the temperature of the plating liquid L1 and the reactivity of the plating processing is not identical between the opening portion of the recess and the bottom and central portions of the recess.

After activating the plating liquid L1 by raising the temperature of the plating liquid L1 to a temperature at which the plating reaction actively proceeds (that is, a plating temperature), the temperature of the plating liquid L1 is lowered to a temperature at which the plating reaction is relatively inhibited. In this case, in the opening portion of the recess where a sufficient amount of the plating liquid L1 exists nearby, the plating reaction is suppressed with the decrease of the temperature of the plating liquid L1, and some of the copper once precipitated may be dissolved again in the plating liquid L1 by the complexing agent. Meanwhile, in the bottom and central portions of the recess where the seed layer or the precipitated copper exists in a limited space, even if the temperature of the plating liquid L1 once activated is reduced, electrons emitted from the reducing agent in the plating liquid L1 are consumed and the plating reaction is carried on, so that the precipitation of the plating copper may be continued.

Taking advantage of this difference in the reactivity depending on the locations in the recess, the electroless plating processing can be performed as follows. That is, after once activating the plating liquid L1 by increasing the temperature of the plating liquid L1, the temperature of the plating liquid L1 is lowered on the processing surface Sw of the substrate W. At this time, the plating reaction in the opening portion is suppressed to the extent that the opening portion of the recess is not closed by the precipitated copper, and in some cases, the copper in the opening portion of the recess is dissolved in the plating liquid L1. Meanwhile, in the bottom portion and the central portion of the recess, the plating reaction is continued, and the copper is precipitated. Therefore, formation of a void can be suppressed, and the copper (plating metal) can be properly filled in the entire recess.

In order to properly fill the recess with the copper while suppressing the formation of the void as stated above, the temperature control of the plating liquid L1 needs to be properly performed under the control of the controller 3 in consideration of the plating liquid L1, the seed layer, and other processing conditions. Below, typical exemplary embodiments regarding the temperature control of the plating liquid L1 will be described. The temperature control of the plating liquid L1 in each exemplary embodiment is performed as the controller 3 (refer FIG. 1) controls the individual components of the plating device 5.

In the following exemplary embodiments, ‘supply of the plating liquid L1 onto the substrate W’ to ‘filling of the copper (plating metal) in the recess’ will be mainly described. A processing which is not specified in the following description may be performed before or after each process. By way of example, a cleaning processing for the processing surface Sw of the substrate W using the cleaning liquid L2 and a rinsing processing for the processing surface Sw using the rinse liquid L3 may be performed prior to the supply of the plating liquid L1. Further, after the copper is filled in the recess, a rinsing processing for the processing surface Sw of the substrate W using the rinse liquid L3 and a drying processing for the processing surface Sw may be performed, and, afterwards, the substrate W may be taken out from the substrate holder 52 and carried out from the plating device 5. A specific method of each processing is not particularly limited. For example, although the drying processing of the substrate W is typically performed by rotating the substrate W at a high speed, drying of the processing surface Sw may be accelerated by jetting an inert gas to the substrate W from the inert gas supply 66.

### First Exemplary Embodiment

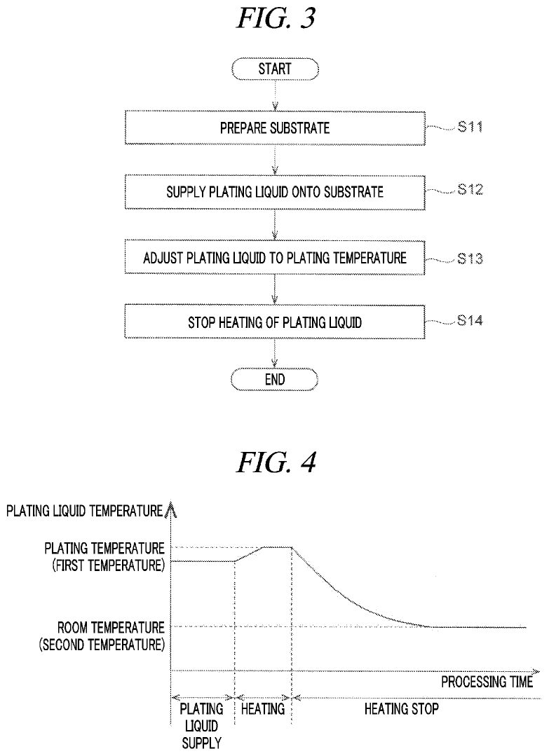

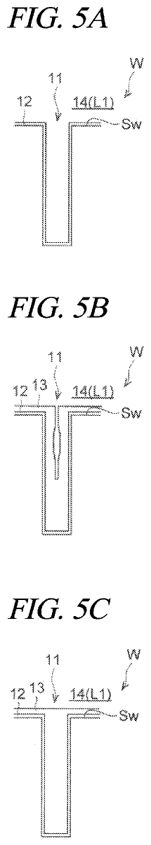

FIG. 3 is a flowchart illustrating an example of an electroless plating processing according to a first exemplary embodiment. FIG. 4 is a graph showing an example of a relationship between a processing time and a temperature of the plating liquid L1 in the electroless plating processing according to the first exemplary embodiment. FIG. 5A to FIG. 5C are diagrams illustrating cross sectional states of a recess 11 of the substrate W in the electroless plating processing according to the first exemplary embodiment.

In the present exemplary embodiment, the substrate W is held by the substrate holder 52 to be in a standby state, as shown in FIG. 2 (S11 of FIG. 3). A front surface (i.e., the processing surface Sw) of the substrate W includes a plurality of recesses 11, and the seed layer 12 is stacked on these recesses 11 (see FIG. 5A). The recess 11 is not particularly limited. Typically, the recess 11 may be a trench (a groove for accommodating therein an upper wiring formed in an insulating film) or a via (a hole connecting the upper wiring and a lower wiring).

The seed layer 12 may be made of any material that functions as an electrode for supplying electrons necessary for reducing metal ions in the plating liquid L1 to a plating portion. In the present exemplary embodiment, the seed layer 12 is formed of a copper film for reducing copper ions. Although not shown, a barrier layer (for example, tantalum (Ta) or tantalum nitride (TaN)) for suppressing diffusion of the plating metal (copper in the present example) may be provided between the seed layer 12 and the processing surface Sw of the substrate W. Further, the seed layer 12 itself may function as the barrier layer.

After the substrate W is prepared, the nozzle arm 56 is placed at the discharge position above the substrate W, and the plating liquid L1 (that is, an electroless plating liquid) is supplied on the processing surface Sw from the plating liquid supply 53 (that is, the plating liquid nozzle 531) (S12). Accordingly, each recess 11 is filled with the plating liquid L1 to form a liquid film 14 of the plating liquid L1 on the processing surface Sw (see FIG. 5A). At this time, the plating liquid L1 (that is, the liquid film 14) on the substrate W has a temperature higher than a room temperature (that is, a normal temperature) (refer to the range indicated by “plating liquid supply” in FIG. 4). The normal temperature is a temperature ranging from 5° C. to 35° C., and the room temperature is typically in the range from 15° C. to 25° C. (for example, about 22° C. to 24° C.).

The plating liquid L1 having landed on the substrate W is affected by the room temperature and the temperature of the substrate W, so that the temperature of this plating liquid L1 usually becomes lower than the temperature thereof immediately after being discharged from the plating liquid nozzle 531. Further, in the range indicated by ‘plating liquid supply’ in FIG. 4, although the temperature of the plating liquid L1 is illustrated to be constant for convenience' sake, the temperature of the plating liquid L1 after landing on the substrate W may actually fluctuate. In the example shown in FIG. 4, in a period during which the plating liquid L1 is supplied on the substrate W, the plating liquid L1 on the substrate W has a temperature slightly lower than a first temperature to be described later. However, the temperature of the plating liquid L1 on the substrate W in the period during which the plating liquid L1 is supplied on the substrate W is not particularly limited. For example, it may be a temperature (for example, a room temperature or a temperature close to the room temperature) significantly lower than the first temperature, or a temperature higher than the first temperature.

After the liquid film 14 of the plating liquid L1 is formed on the processing surface Sw of the substrate W, the nozzle arm 56 is placed at the retreat position, the cover body 6 is placed at the lower position (the position indicated by the solid line in FIG. 2), and the liquid film 14 is heated by the heater 63. That is, the liquid film 14 is regulated to a plating temperature (first temperature) suitable for precipitating the copper (that is, the plating metal) on the seed layer 12 (S13; refer to the range indicated by “heating” in FIG. 4). Accordingly, plating copper 13 is gradually precipitated on the seed layer 12, and the recess 11 is gradually filled with the plating copper 13 (see FIG. 5B). Further, when the temperature of the plating liquid L1 immediately after landing on the substrate W is high enough to induce the plating reaction, the precipitation of the plating copper 13 in the recess 11 takes place even before the temperature of the liquid film 14 is adjusted to the first temperature.

After heating the liquid film 14 on the substrate W to the plating temperature (first temperature), the temperature of the liquid film 14 is lowered from the first temperature to a temperature (second temperature) lower than the first temperature. Although the liquid film 14 may be maintained at the first temperature or a temperature close to the first temperature for a while, the liquid film 14 is adjusted to the second temperature before the opening portion of the recess 11 is closed by the precipitated plating copper 13. In the present exemplary embodiment, the cover body 6 is moved from the lower position to the upper position (the position indicated by the dashed double-dotted line in FIG. 2), and the heater 63 is placed at a position where it does not substantially heat the liquid film 14 on the substrate W. As a result, the liquid film 14 on the substrate W is naturally cooled from the plating temperature (first temperature) toward the room temperature (second temperature) (S14; see the range indicated by “heating stop” in FIG. 4).

By gradually reducing the temperature of the liquid film 14 on the substrate W in this way, the plating reaction in the opening portion of the recess 11 is suppressed, while the plating copper 13 is continuously precipitated in the bottom and central portions of the recess 11. Thus, while the liquid film 14 is cooled from the plating temperature (first temperature) to the room temperature (second temperature), the recess 11 is gradually filled with the plating copper 13 from the bottom portion toward the opening portion thereof, and finally, the entire recess 11 is filled with the plating copper 13 (see FIG. 5C). In this way, the recess 11 is filled with the plating copper 13 (plating metal) starting from the bottom portion thereof so that a void may not be formed.

The series of processes of the electroless plating processing described above are performed under the control of the controller 3 (see FIG. 1). The controller 3 adjusts the liquid film 14 on the substrate W from the plating temperature (first temperature) to the second temperature, and controls the cover body 6 (that is, a temperature adjusting unit) having the heater 63 such that the recess 11 is filled with the precipitated copper starting from the bottom portion thereof so that a void is not formed.

In addition, although the second temperature is set to be the room temperature in the shown example, the second temperature may be higher or lower than the room temperature. For example, after heating the liquid film 14 on the substrate W to the plating temperature (first temperature), the cover body 6 may be moved from the lower position to an intermediate position between the upper position and the lower position in the height direction. In this case, the temperature of the liquid film 14 on the substrate W gradually decreases from the first temperature toward a temperature between the first temperature and the room temperature (second temperature).

Further, the liquid film 14 on the substrate W is heated as the cover body 6 (cover member) having the heater 63 is placed above the processing surface Sw, and the temperature of the liquid film 14 is adjusted as the distance between the processing surface Sw and the heater 63 is changed. Thus, the temperature adjusting unit configured to adjust the temperature of the liquid film 14 on the substrate W includes the cover body 6 (precisely, the heater 63). However, without being limited thereto, the temperature adjusting unit may include other devices and other means capable of changing the temperature of the liquid film 14.

By way of example, the temperature adjusting unit may include the inert gas supply 66 (see FIG. 2). When the temperature of the liquid film 14 on the substrate W is adjusted from the plating temperature (first temperature) to the second temperature, the inert gas supply 66 may supply the inert gas to a gap between the processing surface Sw of the substrate and the cover body 6 (particularly, the first ceiling plate 611). In this case, a gas in the gap between the substrate W and the cover body 6 is replaced by the newly supplied inert gas, and evaporation of the plating liquid L1 on the substrate W is accelerated. As a result, the temperature of the liquid film 14 on the substrate W may be reduced. In addition, the temperature of the liquid film 14 on the substrate W may be adjusted by changing a heat generation state of the heater 63 (for example, an on/off state of power supply to the heater 63) under the control of the controller 3. By turning off the power supply to the heater 63 in the state that the cover body 6 is placed at the lower position, the temperature of the liquid film 14 on the processing surface Sw can be gently reduced in the state that the processing surface Sw of the substrate W is covered with the cover body 6.

### Second Exemplary Embodiment

In a second exemplary embodiment, parts identical or similar to those of the first exemplary embodiment described above will be assigned same reference numerals, and detailed description thereof will be omitted.

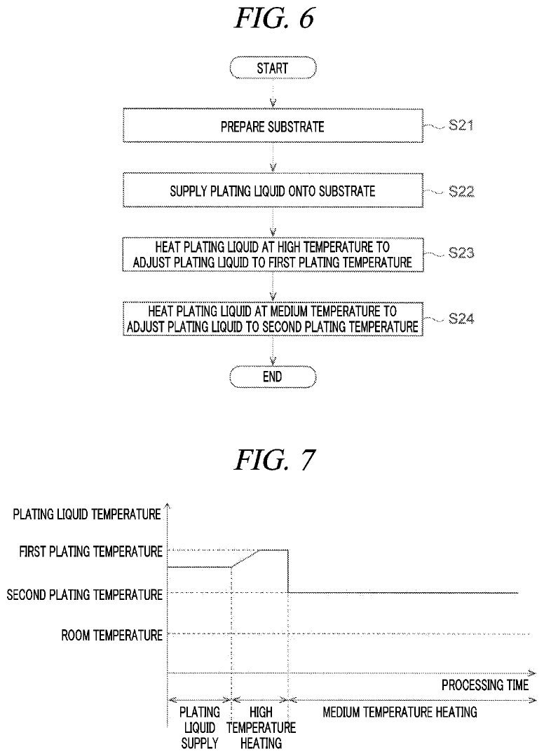

FIG. 6 is a flowchart illustrating an example of an electroless plating processing according to a second exemplary embodiment. FIG. 7 is a graph showing an example of a relationship between a processing time and a temperature of the plating liquid L in the electroless plating processing according to the second exemplary embodiment.

In the present exemplary embodiment, when adjusting the temperature of the liquid film 14 on the substrate W from the plating temperature (first temperature) to the second temperature by lowering the temperature of the liquid film 14 on the substrate W, the plating liquid L1 having a temperature lower than the first temperature is supplied to the processing surface Sw of the substrate W. Accordingly, the temperature of the plating liquid L1 drops rapidly in a short time as compared to natural cooling. For convenience' sake, FIG. 7 illustrates a state in which the temperature of the liquid film 14 on the substrate W instantaneously changes from a first plating temperature to a second plating temperature. Actually, however, it takes some time for the temperature of the liquid film 14 on the substrate W to change from the first plating temperature to the second plating temperature.

In the present exemplary embodiment, the substrate W is prepared on the substrate holder 52 (S21 of FIG. 6), and the plating liquid L1 is supplied onto the substrate W from the plating liquid nozzle 531 (S22; refer to the range indicated by ‘plating liquid supply’ in FIG. 7), the same as in the above-described first exemplary embodiment. Then, by placing the cover body 6 at the lower position, the liquid film 14 on the substrate W is heated to adjust the temperature of the liquid film 14 to the first plating temperature (first temperature) (S23; refer to the range indicated by ‘high temperature heating’ in FIG. 7).

Thereafter, the cover body 6 is moved from the lower position to the upper position, and the nozzle arm 56 is moved from the retreat position to the discharge position to supply the new plating liquid L1 onto the processing surface Sw of the substrate W from the plating liquid supply 53 (plating liquid nozzle 531). The temperature of the plating liquid L1 newly supplied onto the processing surface Sw is lower than the first temperature, typically, equal to or slightly higher or lower than the second plating temperature. As a result, the temperature of the liquid film 14 on the processing surface Sw drops rapidly from the first plating temperature toward the second plating temperature.

After the supply of the new plating liquid L1 from the plating liquid nozzle 531 onto the processing surface Sw of the substrate W is completed, the nozzle arm 56 is moved from the discharge position to the retreat position. Thereafter, the cover body 6 is lowered from the upper position and placed at the intermediate position (the position between the upper position and the lower position in the height direction). As a result, the plating liquid L1 on the substrate W is heated by the heater 63, and the temperature of the liquid film 14 on the processing surface Sw is maintained at the second plating temperature (S24; refer to the range indicated by ‘medium temperature heating’).

In the example shown in FIG. 7, the second plating temperature is a temperature between the plating temperature and the room temperature. The plating liquid L1 of the first plating temperature and the plating liquid L1 of the second plating temperature both precipitate the new plating copper 13 on the processing surface Sw (particularly, on the seed layer 12 and the plating copper 13) by plating reaction. The plating liquid L1 of the first plating temperature is more activated than the plating liquid L1 of the second plating temperature, and it precipitates the plating copper 13 in the entire recess 11. Meanwhile, in case of the plating liquid L1 of the second plating temperature, the plating reaction at the bottom portion and the central portion of the recess 11 is more active than the plating reaction at the opening portion of the recess 11, so that a relatively large amount of plating copper 13 is precipitated in the bottom and central portions of the recess. Accordingly, the recess 11 is filled with the plating copper 13 starting from the bottom portion thereof, so that formation of a void in the recess 11 is suppressed.

### Third Exemplary Embodiment

In a third exemplary embodiment, parts identical or similar to those of the first exemplary embodiment described above will be assigned same reference numerals, and detailed description thereof will be omitted.

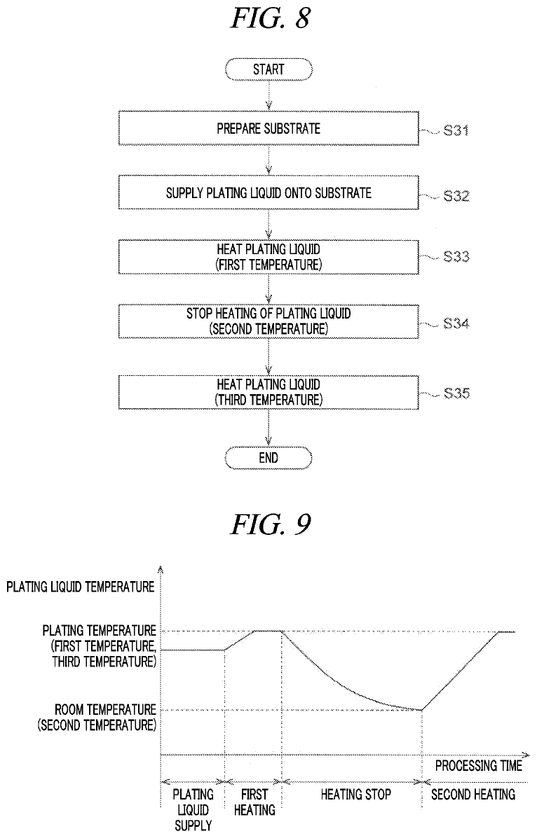

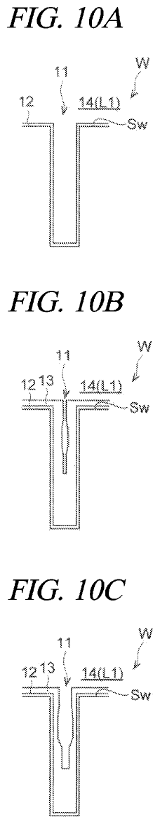

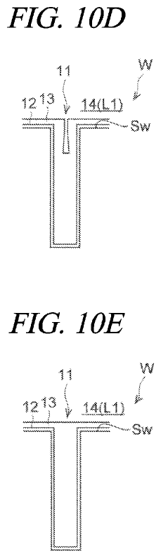

FIG. 8 is a flowchart showing an example of an electroless plating processing according to the third exemplary embodiment. FIG. 9 is a graph showing an example of a relationship between a processing time and a temperature of the plating liquid L1 in the electroless plating processing according to the third exemplary embodiment. FIG. 10A to FIG. 10E are diagrams showing cross sectional states of the recess 11 of the substrate W in the electroless plating processing according to the third exemplary embodiment.

In the present exemplary embodiment, after the liquid film 14 on the substrate W is adjusted to the second temperature, the liquid film 14 is heated to a third temperature which is higher than the second temperature and at which the plating copper 13 is precipitated. By heating the liquid film 14 to the third temperature at an appropriate timing, filling the recess 11 with the plating copper 13 can be speeded up while suppressing the opening portion of the recess 11 from being closed by the plating copper 13.

In the present exemplary embodiment, the substrate W is prepared on the substrate holder 52 (S31 of FIG. 8), and the plating liquid L1 is supplied onto the substrate W from the plating liquid nozzle 531 (S32; refer to the range indicated by ‘plating liquid supply’ in FIG. 9 and FIG. 10A), the same as in the above-described first exemplary embodiment. Then, by placing the cover body 6 at the lower position, the plating liquid L1 on the substrate W is heated to adjust the temperature of the liquid film 14 on the processing surface Sw to the plating temperature (first temperature) (S33; refer to the range indicated by ‘first heating’ in FIG. 9).

Thereafter, the cover body 6 is moved from the lower position to the upper position, and the liquid film 14 on the substrate W is naturally cooled from the plating temperature (first temperature) to the room temperature (second temperature) (S34; refer to the range indicated by ‘heating stop’ in FIG. 9). In this cooling process, in a period during which the temperature of the liquid film 14 is relatively high (for example, in a period during which the temperature of the liquid film 14 is relatively close to the first temperature), copper is gradually precipitated on the seed layer 12, so that the recess 11 is gradually filled with the plating copper 13 (see FIG. 10B). Meanwhile, in a period during which the temperature of the liquid film 14 is relatively low (for example, in a period during which the temperature of the liquid film 14 is relatively close to the second temperature) in the cooling process, reactivity of the electroless plating processing is weakened. The liquid film 14 having the temperature close to the second temperature or the second temperature dissolves the plating copper 13 at least in the opening portion of the recess 11 (see FIG. 10C) and thus reduces the plating copper 13. In this way, since some of the plating copper 13 in the recess 11 disappears by being eluted into the liquid film 14, the diameter of the space of the opening portion of the recess 11 (that is, the diameter of the opening portion of the recess 11) can be enlarged.

Thereafter, the cover body 6 is moved from the upper position to the lower position, and the plating liquid L1 on the substrate W is heated by the heater 63, so that the temperature of the liquid film 14 on the processing surface Sw is adjusted to the plating temperature (third temperature) (S35; refer to the range indicated by ‘second heating’ in FIG. 9). As a result, the plating reaction proceeds in the liquid film 14, and the recess 11 is gradually filled with the plating copper 13 starting from the bottom portion toward the opening portion thereof (see FIG. 10D), and finally, the entire recess 11 is filled with the plating copper 13 (see FIG. 10E).

As described above, according to the present exemplary embodiment, some of the plating copper 13 once precipitated in the recess 11 is dissolved in the liquid film 14, so that the diameter of the space of the opening portion of the recess 11 is enlarged. Thus, closing of the opening portion by the copper before the completion of the filling of the copper in the bottom or central portion of the recess can be effectively avoided.

Further, in the example shown in FIG. 9, although the first temperature and the third temperature are set to be the same temperature, they may be different temperatures. The second temperature may not be the room temperature, and it may be a temperature higher than or lower than the room temperature. Typically, by adjusting the position of the cover body 6 (precisely, the heater 63) in the height direction, the first temperature and the third temperature can be made to be different from each other, or the second temperature can be made to be higher than the room temperature. In addition, it may be also possible to set the second temperature to be lower than the room temperature by increasing the amount (flow rate) of the inert gas supplied from the inert gas supply 66 (that is, the gas nozzle 661) into the gap between the cover body 6 and the substrate W or by decreasing the temperature of the inert gas.

Furthermore, although the above description has been provided for the example where the plating copper 13 is eluted into the liquid film 14 in the recess 11 (particularly, the opening portion thereof) until the heating of the liquid film 14 is started again after the temperature of the liquid film 14 is lowered from the first temperature to the second temperature, the plating copper 13 may not be eluted into the liquid film 14 in the recess 11. For example, when the liquid film 14 on the substrate W has the second temperature or a temperature close to the second temperature, the film forming rate of the plating copper 13 in the opening portion of the recess 11 may be lower than the film forming rate of the plating copper 13 in the bottom or central portion of the recess 11, or the film formation of the plating copper 13 may be substantially stopped thereat.

### Fourth Exemplary Embodiment

In a fourth exemplary embodiment, parts identical or similar to those of the second exemplary embodiment and the third exemplary embodiment described above will be assigned same reference numerals, and detailed description thereof will be omitted.

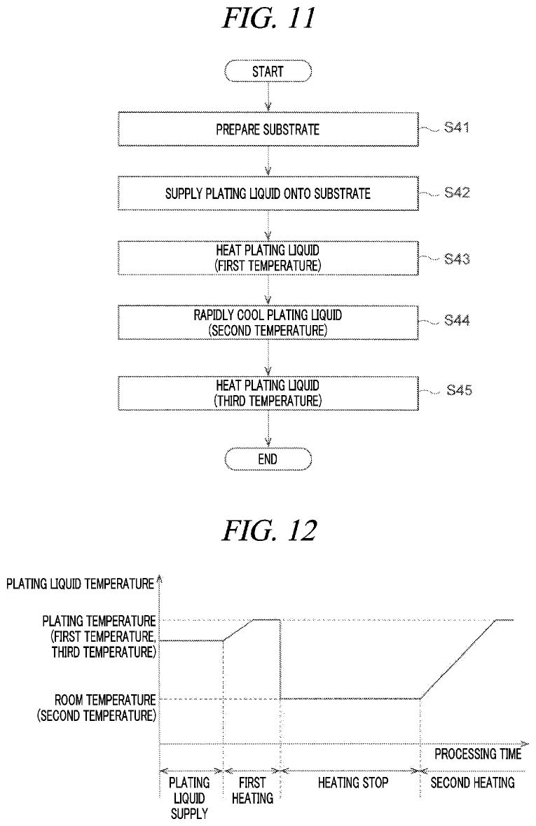

FIG. 11 is a flowchart illustrating an example of an electroless plating processing according to the fourth exemplary embodiment. FIG. 12 is a graph showing an example of a relationship between a processing time and a temperature of the plating liquid L1 in the electroless plating processing according to the fourth exemplary embodiment.

In the present exemplary embodiment, the substrate W is prepared on the substrate holder 52 (S41 of FIG. 11), and the plating liquid L1 is supplied onto the substrate W from the plating liquid supply 53 (plating liquid nozzle 531) (S42; refer to the range indicated by ‘plating liquid supply’ in FIG. 12), the same as in the above-described third exemplary embodiment. Thereafter, the cover body 6 is placed at the lower position to heat the plating liquid L1 on the substrate W, so the temperature of the liquid film 14 on the processing surface Sw is adjusted to the plating temperature (first temperature) (S43; refer to the range indicated by ‘first heating’ in FIG. 12).

Thereafter, the cover body 6 is moved from the lower position to the upper position, the nozzle arm 56 is moved from the retreat position to the discharge position, and the new plating liquid L1 is supplied onto the processing surface Sw of the substrate W from the plating liquid supply 53 (plating liquid nozzle 531). The temperature of the plating liquid L1 newly supplied onto the processing surface Sw is lower than the first temperature (for example, the room temperature or a temperature below the room temperature). As a result, the temperature of the liquid film 14 on the processing surface Sw drops rapidly from the plating temperature (first temperature) toward the room temperature (second temperature) (S44). For convenience' sake, FIG. 12 shows a state in which the temperature of the liquid film 14 on the substrate W instantaneously changes from the first temperature to the second temperature. Actually, however, it takes some time for the temperature of the liquid film 14 on the substrate W to change from the first temperature to the second temperature.

Thereafter, with the cover body 6 located at the upper position, the substrate W and the liquid film 14 are placed under a room temperature environment for a while (refer to the range indicated by “heating stop” in FIG. 12). During at least a part of this period (for example, the first half thereof), the plating reaction in the opening portion of the recess 11 is suppressed, whereas the plating copper 13 is continuously precipitated in the bottom and central portions of the recess 11. Further, during at least a part of this period (for example, the second half thereof), some of the plating copper 13 in the recess 11 may be dissolved in the liquid film 14, resulting in enlargement of the diameter of the space of the opening portion of the recess 11.

Subsequently, the cover body 6 is moved from the upper position to the lower position, and the plating liquid L1 on the substrate W is heated by the heater 63 so that the temperature of the liquid film 14 on the processing surface Sw is adjusted to the plating temperature (third temperature) (S45; refer to the range indicated by ‘second heating’ in FIG. 12). As a result, the plating reaction proceeds in the liquid film 14, and finally, the entire recess 11 is filled with the copper.

In addition, in the example shown in FIG. 12, although the first temperature and the third temperature are set to be the same temperature, they may be different temperatures. The second temperature may not be the room temperature, and it may be a temperature higher than or lower than the room temperature.

Moreover, although the above description has been provided for the example where the plating copper 13 is eluted into the liquid film 14 in the recess 11 (particularly, in the opening portion thereof) until the temperature of the liquid film 14 is raised again to the third temperature after being reduced from the first temperature to the second temperature, the plating copper 13 may not be eluted into the liquid film 14 in the recess 11.

### MODIFICATION EXAMPLE

To decrease the temperature of the plating liquid L1, active cooling and natural cooling may be combined. By way of example, in the second exemplary embodiment (see FIG. 7), after reducing the temperature of the liquid film 14 to the second plating temperature by supplying the new plating liquid L1 onto the substrate W, the plating film 14 may be then cooled naturally. Further, in the fourth exemplary embodiment (see FIG. 12), after reducing the temperature of the liquid film 14 to the “temperature between the first temperature and the room temperature” by supplying the new plating liquid L1 onto the substrate W, the liquid film 14 may be naturally cooled to the room temperature. When performing the natural cooling, it is desirable that the cover body 6 is placed at a position where the temperature of the liquid film 14 on the substrate W does not rise due to the heat from the heater 63. For example, by locating the cover body 6 at the upper position (the position indicated by the dashed double-dotted line in FIG. 2), the liquid film 14 on the substrate W can be naturally cooled to the room temperature.

In the electroless plating processing (substrate liquid processing method) described above, the process of raising the temperature of the liquid film 14 on the substrate W to accelerate the precipitation of the plating copper 13 and the process of lowering the temperature of the liquid film 14 may be repeated alternately. For example, in the above-described third exemplary embodiment (see FIG. 9) and fourth exemplary embodiment (see FIG. 12), after raising the temperature of the liquid film 14 on the substrate W to the third temperature, the temperature of the liquid film 14 may be lowered from the third temperature and then increased later. In this case, the precipitation of the plating copper 13 in the recess 11 can be gradually performed from a lower portion of the recess 11 toward an upper portion thereof. Therefore, formation of a void can be avoided effectively.

It should be noted that the above-described exemplary embodiments are illustrative in all aspects and are not anyway limiting. The above-described exemplary embodiments and modification examples may be omitted, replaced and modified in various ways without departing from the scope and the spirit of claims. By way of example, the exemplary embodiments and the modification examples described above may be combined with each other, or an exemplary embodiment other than those described in the preset disclosure may be combined with the above-described exemplary embodiments or modification examples.

Furthermore, a technical category for embodying the above-described technical concept is not particularly limited. By way of example, the above-described substrate liquid processing apparatus may be applied to another apparatus. Moreover, the above-described technical concept may be embodied by a computer-executable program for executing one or multiple sequences (processes) included in the above-described substrate liquid processing method on a computer. Further, the above-described technical concept may be embodied by a computer-readable non-transitory recording medium in which such a computer-executable program is stored.

### EXPLANATION OF CODES

11: Recess

12: Seed layer

13: Plating copper

14: Liquid film

L1: Plating liquid

Sw: Processing surface

W: Substrate

1. A substrate liquid processing method, comprising:
preparing a substrate having a surface including a recess on which a seed layer is stacked;
supplying an electroless plating liquid onto the surface of the substrate to fill the recess with the electroless plating liquid while forming a liquid film of the electroless plating liquid on the surface; and
adjusting a temperature of the liquid film from a first temperature at which a metal is precipitated on the seed layer to a second temperature lower than the first temperature to fill the recess with the metal starting from a bottom portion of the recess such that a void is not formed therein.

2. The substrate liquid processing method of claim 1,
wherein the second temperature is a room temperature.

3. The substrate liquid processing method of claim 1,
wherein the liquid film is adjusted to the second temperature before an opening portion of the recess is closed by the metal precipitated thereat.

4. The substrate liquid processing method of claim 1, further comprising:
heating, after the adjusting of the temperature of the liquid film to the second temperature, the liquid film to a third temperature which is higher than the second temperature and at which the metal is precipitated.

5. The substrate liquid processing method of claim 1,
wherein increasing the temperature of the liquid film to accelerate precipitation of the metal and decreasing the temperature of the liquid film are repeated alternately.

6. The substrate liquid processing method of claim 4,
wherein the liquid film having the second temperature dissolves and reduces the metal at least in an opening portion of the recess.

7. The substrate liquid processing method of claim 1,
wherein the liquid film is heated as a cover member having a heater is placed above the surface of the substrate, and
the temperature of the liquid film is adjusted as a distance between the surface of the substrate and the heater is changed.

8. The substrate liquid processing method of claim 7,
wherein, in the adjusting of the temperature of the liquid film to the second temperature, a gas is supplied into a gap between the surface of the substrate and the cover member.

9. The substrate liquid processing method of claim 1,
wherein, in the adjusting of the temperature of the liquid film to the second temperature, the electroless plating liquid having a temperature lower than the first temperature is supplied onto the surface of the substrate.

10. A substrate liquid processing apparatus, comprising:
a plating liquid supply configured to supply an electroless plating liquid onto a surface of a substrate including a recess on which a seed layer is stacked, to fill the recess with the electroless plating liquid while forming a liquid film of the electroless plating liquid on the surface;
a temperature adjusting unit configured to adjust a temperature of the liquid film; and
a controller configured to control the temperature adjusting unit,
wherein the controller controls the temperature adjusting unit to adjust the temperature of the liquid film from a first temperature at which a metal is precipitated on the seed layer to a second temperature lower than the first temperature to fill the recess with the metal starting from a bottom portion of the recess such that a void is not formed therein.

11. A computer-readable recording medium having stored thereon computer-executable instructions that, in response to execution, cause an apparatus to perform a substrate liquid processing method comprising:
preparing a substrate having a surface including a recess on which a seed layer is stacked;
supplying an electroless plating liquid onto the surface of the substrate to fill the recess with the electroless plating liquid while forming a liquid film of the electroless plating liquid on the surface; and
adjusting a temperature of the liquid film from a first temperature at which a metal is precipitated on the seed layer to a second temperature lower than the first temperature to fill the recess with the metal starting from a bottom portion of the recess such that a void is not formed therein.
